(19) United States
(12) Patent Application Publication
(10) Pub. No.: US 2026/0068482 A1
(43) Pub. Date: Mar. 5, 2026

(54) DISPLAY DEVICE

(71) Applicant: LG Display Co., Ltd., Seoul (KR)

(72) Inventors: SeokHyun KIM, Paju-si (KR); KwanSoo KIM, Paju-si (KR); JongWoo PARK, Paju-si (KR); Minji KIM, Paju-si (KR); JiHyun ROH, Paju-si (KR); Soyeong JEONG, Paju-si (KR)

(73) Assignee: LG Display Co., Ltd., Seoul (KR)

(21) Appl. No.: 19/285,980

(22) Filed: Jul. 30, 2025

(30) Foreign Application Priority Data
Sep. 5, 2024 (KR) 10-2024-0120498

(51) Int. Cl. H10K 59/80; H10K 50/17; H10K 59/65; H10K 102/00

(52) U.S. Cl. CPC H10K 59/80523; H10K 50/171; H10K 59/65; H10K 59/80515; H10K 59/80521; H10K 59/879; H10K 2102/351

(57) ABSTRACT

A display device is provided, which is capable of increasing luminous efficiency in the optical area to reduce luminance deviations between the normal area and the optical area. The display device includes a first patterning layer disposed in the transmissive area of the optical area, a second patterning layer disposed in the first emission area of the normal area, and a second cathode electrode disposed in the second emission area of the optical area.

### CROSS-REFERENCE TO RELATED APPLICATION

This application claims priority to Korean Patent Application No. 10-2024-0120498, filed in the Republic of Korea on Sep. 5, 2024, which is hereby expressly incorporated by reference for all purposes as if fully set forth herein into the present application.

### BACKGROUND

### Field

Embodiments of the disclosure relate to a display device.

### Discussion of the Related Art

As the information society develops, demand for display devices for displaying images is increasing in various forms. Various display devices, such as liquid crystal display devices and organic light emitting display devices, are being utilized in recent years.

Further, the display device can provide a detection function to perform a function depending on the light of the ambient environment. To that end, the display device should have various electronic devices (optical electronic devices), such as detection sensors and image sensors (cameras).

Since the electronic device is preferred to receive light from the front of the display device, a transmissive area having a hole would be formed in the cathode electrode in the area where the electronic device is disposed.

Since the transmissive area replaces the emission area where the light emitting element used to be disposed, a luminance difference can occur between the area in which an electronic device is disposed and the area in which no electronic device is disposed.

### BRIEF SUMMARY OF THE DISCLOSURE

According to embodiments of the disclosure, there can be provided a display device for increasing luminous efficiency by disposing the second cathode electrode on the first cathode electrode in the optical area in which the optical electronic device is disposed.

According to embodiments of the disclosure, there can be provided a display device that increases luminous efficiency of an optical area and reduces a luminance deviation between the optical area and the normal area.

According to embodiments of the disclosure, there can be provided a display device capable of lower power driving by inducing a micro cavity effect between the first capping layer and the second capping layer disposed on the light emitting element and the second cathode electrode to increase luminous efficiency.

According to embodiments of the disclosure, there can be provided a display device capable of shielding electromagnetic waves in UV bands, radiated from the outside of the display panel, by disposing the second cathode electrode in the optical area.

Embodiments of the disclosure can provide a display device comprising a substrate including a first area including a plurality of first emission areas and a second area including a plurality of second emission areas and a plurality of transmissive areas, a plurality of first anode electrodes respectively disposed in the plurality of first emission areas and positioned on the substrate, a plurality of second anode electrodes respectively disposed in the plurality of second emission areas and positioned on the substrate, a plurality of first light emitting layers disposed on the plurality of first anode electrodes, a plurality of second light emitting layers disposed on the plurality of second anode electrodes, a first cathode electrode disposed on the plurality of first light emitting layers and the plurality of second light emitting layers, a second cathode electrode disposed in the plurality of second emission areas and positioned on the first cathode electrode, a first patterning layer disposed in the plurality of transmissive areas and adjacent to a side surface of the first cathode electrode in a first direction (e.g., horizontal direction), and a second patterning layer disposed in the plurality of first emission areas, positioned on the first cathode electrode, and adjacent to a side surface of the second cathode electrode in the first direction.

Embodiments of the disclosure can provide a display device comprising a substrate, a plurality of anode electrodes positioned on the substrate, a plurality of first light emitting layers and a plurality of second light emitting layers respectively disposed on the plurality of anode electrodes, a first cathode electrode disposed on the plurality of first light emitting layers and the plurality of second light emitting layers, a patterning layer positioned on the first cathode electrode and overlapping the plurality of first light emitting layers in a second direction (e.g., vertical direction), and a second cathode electrode disposed on the first cathode electrode and overlapping the plurality of second light emitting layer in the second direction.

According to embodiments of the disclosure, there can be provided a display device for increasing luminous efficiency by disposing the second cathode electrode on the first cathode electrode in the optical area in which the optical electronic device is disposed.

According to embodiments of the disclosure, there can be provided a display device that increases luminous efficiency of an optical area and reduces a luminance deviation between the optical area and the normal area.

According to embodiments of the disclosure, there can be provided a display device capable of lower power driving by inducing a micro cavity effect between the first capping layer and the second capping layer disposed on the light emitting element and the second cathode electrode to increase luminous efficiency.

According to embodiments of the disclosure, there can be provided a display device capable of shielding electromagnetic waves in ultraviolet (UV) bands, radiated from the outside of the display panel, by disposing the second cathode electrode in the optical area.

### BRIEF DESCRIPTION OF THE DRAWINGS

The above and other objects, features, and advantages of the disclosure will be more clearly understood from the following detailed description, taken in conjunction with the accompanying drawings, in which:

FIGS. 1, 2, and 3 illustrate a display device according to embodiments of the disclosure;

FIG. 4 is a view illustrating a configuration of a system of a display device according to embodiments of the disclosure;

FIG. 5 illustrates a display panel according to an embodiment of the disclosure;

FIG. 6 is a view illustrating an arrangement of subpixels in two areas included in a display area of a display panel according to embodiments of the disclosure;

FIG. 7 is a schematic cross-sectional view illustrating a portion of a first emission area disposed in a normal area and a schematic cross-sectional view illustrating a portion of a second emission area and a transmissive area disposed in an optical area as illustrated in FIG. 6;

FIG. 8 is a cross-sectional view taken along the dashed line A-A′ in the normal area and the dashed line B-B′ in the optical area illustrated in FIG. 6;

FIG. 9 is a schematic cross-sectional view for each area of a display panel when a second cathode electrode is disposed in a second emission area according to embodiments of the disclosure;

FIG. 10 is a schematic cross-sectional view for each area of a display panel when a first patterning layer is disposed on an electron injection layer in a transmissive area according to embodiments of the disclosure;

FIG. 11 is a view illustrating a normal area and an optical area of a display panel according to embodiments of the disclosure;

FIG. 12 is a view illustrating a normal area and an optical area of a display panel according to embodiments of the disclosure;

FIG. 13 is a view illustrating a normal area and an optical area of a display panel according to embodiments of the disclosure;

FIG. 14 is a view illustrating a normal area and an optical area of a display panel according to embodiments of the disclosure;

FIG. 15 is a subpixel-specific luminance efficiency table for each thickness of a second cathode electrode according to embodiments of the disclosure; and

FIG. 16 is a table showing the degree of shrinkage and luminance degradation over time when a light emitting element is irradiated with an electromagnetic wave in a UV band according to embodiments of the disclosure.

### DETAILED DESCRIPTION OF THE EMBODIMENTS

In the following description of examples or embodiments of the disclosure, reference will be made to the accompanying drawings in which it is shown by way of illustration specific examples or embodiments that can be implemented, and in which the same reference numerals and signs can be used to designate the same or like components even when they are shown in different accompanying drawings from one another. Further, in the following description of examples or embodiments of the disclosure, detailed descriptions of well-known functions and components incorporated herein will be omitted when it is determined that the description can make the subject matter in some embodiments of the disclosure rather unclear. The terms such as “including”, “having”, “containing”, “constituting” “make up of”, and “formed of” used herein are generally intended to allow other components to be added unless the terms are used with the term “only”. As used herein, singular forms are intended to include plural forms unless the context clearly indicates otherwise.

Terms, such as “first”, “second”, “A”, “B”, “(A)”, or “(B)” can be used herein to describe elements of the disclosure. Each of these terms is not used to define essence, order, sequence, or number of elements etc., but is used merely to distinguish the corresponding element from other elements.

When it is mentioned that a first element “is connected or coupled to”, “contacts or overlaps” etc. a second element, it should be interpreted that, not only can the first element “be directly connected or coupled to” or “directly contact or overlap” the second element, but a third element can also be “interposed” between the first and second elements, or the first and second elements can “be connected or coupled to”, “contact or overlap”, etc. each other via a fourth element. Here, the second element can be included in at least one of two or more elements that “are connected or coupled to”, “contact or overlap”, etc. each other.

When time relative terms, such as “after,” “subsequent to,” “next,” “before,” and the like, are used to describe processes or operations of elements or configurations, or flows or steps in operating, processing, manufacturing methods, these terms can be used to describe non-consecutive or non-sequential processes or operations unless the term “directly” or “immediately” is used together.

In addition, when any dimensions, relative sizes etc. are mentioned, it should be considered that numerical values for an elements or features, or corresponding information (e.g., level, range, etc.) include a tolerance or error range that can be caused by various factors (e.g., process factors, internal or external impact, noise, etc.) even when a relevant description is not specified. Further, the term “may” fully encompasses all the meanings of the term “can”.

Hereinafter, various embodiments of the disclosure are described in detail with reference to the accompanying drawings. All the components of each display device/apparatus according to all embodiments of the disclosure are operatively coupled and configured.

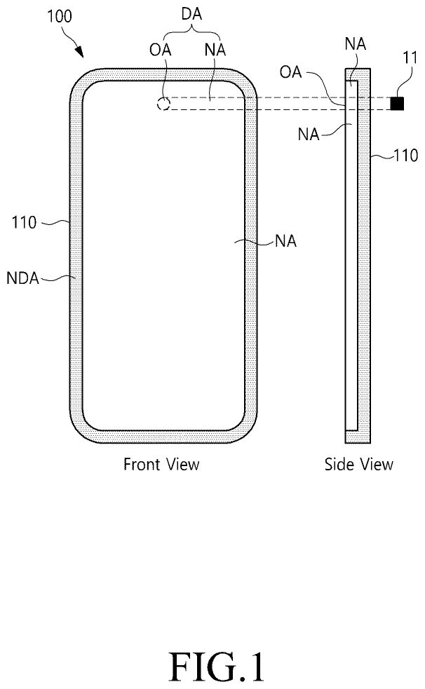

FIGS. 1, 2, and 3 illustrate a display device 100 according to embodiments of the disclosure.

Referring to FIGS. 1, 2, and 3, the display device 100 according to embodiments of the disclosure can include a display panel 110 for displaying images and one or more optical electronic devices 11 and 12.

The display panel 110 can include a display area DA in which images (videos) can displayed and a non-display area NDA in which no image is displayed.

A plurality of subpixels can be disposed in the display area DA, and various signal lines for driving the plurality of subpixels can be disposed in the display area AA.

The non-display area NDA can be an area outside the display area DA. In the non-display area NDA, various signal lines can be disposed, and various driving circuits can be connected thereto. The non-display area NDA can be bent to be invisible from the front or can be covered by a case. The non-display area NDA is also referred to as a bezel or a bezel area.

In the display device 100 according to embodiments of the disclosure, one or more optical electronic devices 11 and 12 are electronic components that are provided and installed separately from the display panel 110 and positioned under the display panel 110 (side opposite to the viewing surface).

Light enters the front surface (viewing surface) of the display panel 110 and passes through the display panel 110 to one or more optical electronic devices 11 and 12 positioned under the display panel 110 (opposite to the viewing surface). For example, the light passing through the display panel 110 can include visible light, infrared light, or ultraviolet light.

The one or more optical electronic devices 11 and 12 can be devices that receive the light transmitted through the display panel 110 and perform a predetermined function according to the received light. For example, the one or more optical electronic devices 11 and 12 can include one or more of a capture device, such as a camera (image sensor), and a detection sensor, such as a proximity sensor and an illuminance sensor. For example, the detection sensor can be an infrared sensor.

In the display panel 110 according to embodiments of the disclosure, the display area DA can include a normal area NA and one or more optical areas OA1 and OA2. The one or more optical areas OA1 and OA2 can be areas overlapping the one or more optical electronic devices 11 and 12.

According to the example of FIG. 1, the display area DA can include the normal area NA and the optical area OA. At least a portion of the optical area OA can overlap the first optical electronic device 11.

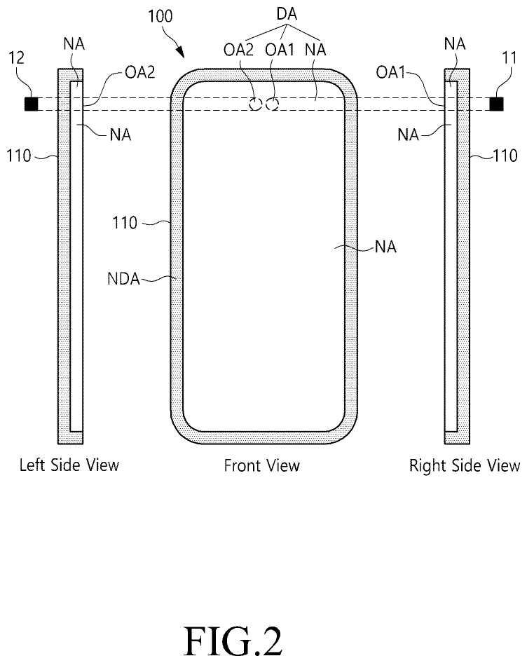

According to the example of FIG. 2, the display area DA can include a normal area NA, a first optical area OA1, and a second optical area OA2. In the example of FIG. 2, the normal area NA can be present between the first optical area OA1 and the second optical area OA2. At least a portion of the first optical area OA1 can overlap the first optical electronic device 11, and at least a portion of the second optical area OA2 can overlap the second optical electronic device 12.

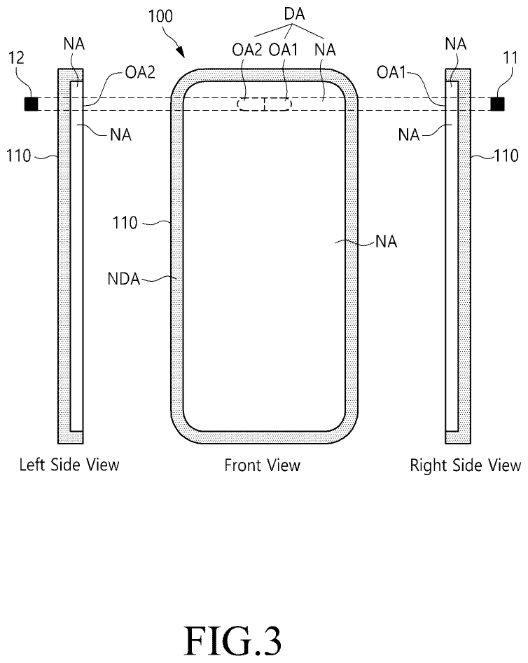

According to the example of FIG. 3, the display area DA can include a normal area NA, a first optical area OA1, and a second optical area OA2. In the example of FIG. 3, the normal area NA is not present between the first optical area OA1 and the second optical area OA2. In other words, the first optical area OA1 and the second optical area OA2 touch each other. At least a portion of the first optical area OA1 can overlap the first optical electronic device 11, and at least a portion of the second optical area OA2 can overlap the second optical electronic device 12.

The one or more optical areas OA1 and OA2 should have both an image display structure and a light transmission structure. In other words, since the one or more optical areas OA1 and OA2 are partial areas of the display area DA, emission areas of subpixels for displaying images should be disposed in the one or more optical areas OA1 and OA2. A light transmission structure for transmitting light to the one or more optical electronic devices 11 and 12 should be formed in one or more optical areas OA1 and OA2.

The one or more optical electronic devices 11 and 12 are devices that require light reception, but are positioned behind (i.e., below, opposite to the viewing surface) the display panel 110 to receive the light transmitted through the display panel 110. The one or more optical electronic devices 11 and 12 are not exposed on the front surface (viewing surface) of the display panel 110. Therefore, when the user looks at the front surface of the display panel 110, the optical electronic devices 11 and 12 are not visible to the user.

For example, the first optical electronic device 11 can be a camera, and the second optical electronic device 12 can be a detection sensor, such as a proximity sensor or an illuminance sensor. For example, the detection sensor can be an infrared sensor that detects infrared rays. Conversely, the first optical electronic device 11 can be a detection sensor, and the second optical electronic device 12 can be a camera.

Hereinafter, for convenience of description, it is assumed that the first optical electronic device 11 is a camera and the second optical electronic device 12 is an infrared (IR)-based detection sensor. The camera can be a camera lens or an image sensor.

If the first optical electronic device 11 is a camera, the camera can be a front camera that is positioned behind (below) the display panel 110 but captures forward of the display panel 110. Accordingly, the user can take a photograph through the camera invisible to the viewing surface while viewing the viewing surface of the display panel 110.

The normal area NA and one or more optical areas OA1 and OA2 included in the display area DA are areas that can display images, but the normal area NA is an area that does not require a light transmission structure to be formed, and the one or more optical areas OA1 and OA2 are areas that require a light transmission structure to be formed.

Accordingly, the one or more optical areas OA1 and OA2 should have a transmittance higher than or equal to a certain level, and the normal area NA can have no light transmittance or a lower transmittance less than the certain level.

For example, the number of subpixels per unit area in one or more optical areas OA1 and OA2 can be smaller than the number of subpixels per unit area in the normal area NA. In other words, the resolution of one or more optical areas OA1 and OA2 can be lower than the resolution of the normal area NA. Here, the number of subpixels per unit area can be meant to be equivalent to resolution, or pixel density, or pixel integration degree. For example, the unit for the number of subpixels per unit area can be pixels per inch (PPI), which means the number of pixels in one inch.

For example, the number of subpixels per unit area in the first optical area OA1 can be smaller than the number of subpixels per unit area in the normal area NA. The number of subpixels per unit area in the second optical area OA2 can be larger than or equal to the number of subpixels per unit area in the first optical area OA1 and be smaller than the number of subpixels per unit area in the normal area NA.

Meanwhile, as one method for increasing the transmittance of at least one of the first optical area OA1 and the second optical area OA2, a pixel density differential design scheme can be applied as described above. According to the pixel density differential design scheme, the display panel 110 can be designed so that the number of subpixels per unit area of at least one of the first optical area OA1 and the second optical area OA2 is larger than the number of subpixels per unit area of the normal area NA.

Hereinafter, for convenience of description, it is assumed in the following description that, to increase the transmittance of at least one of the first optical area OA1 and the second optical area OA2, the pixel density differential design scheme is applied. Accordingly, the number of subpixels per unit area is small, as described below, can be an expression corresponding to the subpixel size being small, and that the number of subpixels per unit area is large can be an expression corresponding to the subpixel size being large.

The first optical area OA1 can have various shapes, such as a circle, an ellipse, a quadrangle, a hexagon, or an octagon. The second optical area OA2 can have various shapes, such as a circle, an ellipse, a square, a hexagon, or an octagon. The first optical area OA1 and the second optical area OA2 can have the same shape or different shapes.

Referring to FIG. 3, when the first optical area OA1 and the second optical area OA2 touch, the entire optical area including the first optical area OA1 and the second optical area OA2 can have various shapes, such as a circle, an ellipse, a square, a hexagon, or an octagon. Hereinafter, for convenience of description, each of the first optical area OA1 and the second optical area OA2 is exemplified as having a circular shape.

In the display device 100 according to embodiments of the disclosure, if the first optical electronic device 11 that is not exposed to the outside and is hidden in a lower portion of the display panel 100 is a camera, the display device 100 according to embodiments of the disclosure can be referred to as a display to which under display camera (UDC) technology has been applied.

Accordingly, the display device 100 according to embodiments of the disclosure does not require a notch or camera hole for camera exposure to be formed in the display panel 110, thereby preventing a reduction in the display area DA. Thus, as there is no need to form a notch or camera hole for exposure of the camera in the display panel 110, the size of the bezel area can be reduced, and design restrictions can be freed, thereby increasing the degree of freedom in design.

In the display device 100 according to embodiments of the disclosure, although one or more optical electronic devices 11 and 12 are positioned to be hidden behind the display panel 110, one or more optical electronic devices 11 and 12 should be able to normally perform predetermined functions by normally receiving light.

Further, in the display device 100 according to embodiments of the disclosure, although one or more optical electronic devices 11 and 12 are positioned to be hidden behind the display panel 110 and are positioned to overlap the display area DA, the one or more optical areas OA1 and OA2 overlapping the one or more optical electronic devices 11 and 12 in the display area DA should be capable of normal image display.

Since the above-mentioned first optical area OA1 is designed as a transmittable area, the image display characteristics in the first optical area OA1 can differ from the image display characteristics in the normal area NA.

Further, in designing the first optical area OA1 to enhance the image display characteristics, the transmittance of the first optical area OA1 can be degraded.

Hereinafter, for convenience of description, it is assumed that the display device 100 according to embodiments of the disclosure has the structure of FIG. 1 among FIG. 1, FIG. 2, and FIG. 3. In other words, it is assumed that the display device 100 according to embodiments of the disclosure has one optical area OA. However, this is merely an assumption for convenience of description, and the embodiments of the disclosure are not limited thereto.

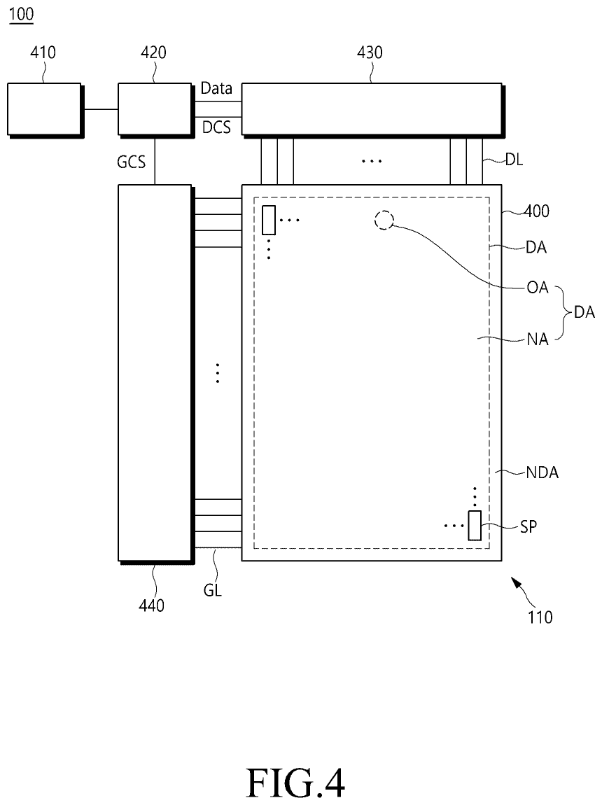

FIG. 4 is a view illustrating a system configuration of a display device 100 according to embodiments of the disclosure.

Referring to FIG. 4, a display device 100 can include a display panel 110 and display driving circuits, as components for displaying images.

The display driving circuits are circuits for driving the display panel 110 and can include a data driving circuit 430, a gate driving circuit 440, and a display controller 420.

The display panel 110 can include a display area DA in which images are displayed and a non-display area NDA in which no image is displayed. The non-display area NDA can be an outer area of the display area DA and be referred to as a bezel area. The whole or part of the non-display area NDA can be an area visible from the front surface of the display device 100 or an area that is bent and not visible from the front surface of the display device 100.

The display panel 110 can include a substrate 400 and a plurality of subpixels SP disposed on the substrate 400. The display panel 110 can further include various types of signal lines to drive the plurality of subpixels SP.

The display device 100 according to embodiments of the disclosure can be a self-emission display device in which the display panel 110 emits light by itself. However, the display device 100 according to embodiments of the disclosure is not limited to a self-luminous display device.

The plurality of data lines DL and the plurality of gate lines GL can cross each other. Each of the plurality of data lines DL can be disposed while extending in a first direction. Each of the plurality of gate lines GL can be disposed while extending in a second direction. Here, the first direction can be a column direction and the second direction can be a row direction. As a variation, the first direction can be the row direction, and the second direction can be the column direction.

The data driving circuit 430 is a circuit for driving the plurality of data lines DL, and can output data signals to the plurality of data lines DL. The gate driving circuit 440 is a circuit for driving the plurality of gate lines GL, and can output gate signals to the plurality of gate lines GL.

The display controller 420 is a device for controlling the data driving circuit 430 and the gate driving circuit 440 and can control driving timings for the plurality of data lines DL and driving timings for the plurality of gate lines GL.

The display controller 420 can supply a data driving control signal DCS to the data driving circuit 430 to control the data driving circuit 430 and can supply a gate driving control signal GCS to the gate driving circuit 440 to control the gate driving circuit 440.

The display controller 420 can receive input image data from the host system 410 and supply image data Data to the data driving circuit 430 based on the input image data.

The data driving circuit 430 can receive digital image data Data from the display controller 420 and can convert the received image data Data into analog data signals and output the analog data signals to the plurality of data lines DL.

The gate driving circuit 440 can receive a first gate voltage corresponding to a turn-on level voltage and a second gate voltage corresponding to a turn-off level voltage, along with various gate driving control signals GCS, generate gate signals, and supply the generated gate signals to the plurality of gate lines GL.

The display device 100 can further include a power supply circuit for supplying various types of power to the display driving circuit.

The display device 100 according to embodiments of the disclosure can be a mobile terminal, such as a smart phone or a tablet, or a monitor or television (TV) in various sizes but, without limited thereto, can be a display in various types and various sizes capable of displaying information or images.

As described above, the display area DA in the display panel 110 can include the normal area NA and an optical area OA. The normal area NA and the optical area OA are areas capable of displaying an image. However, the normal area NA is an area where a light transmission structure is not required to be formed, and the optical area OA is an area in which a light transmission structure is to be formed.

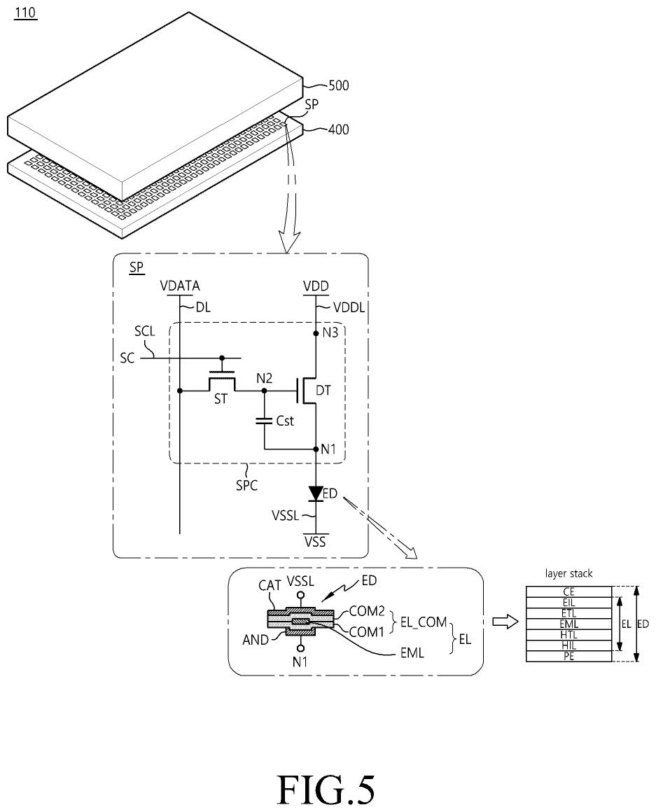

FIG. 5 illustrates a display panel 110 according to an embodiment of the disclosure.

Referring to FIG. 5, a plurality of subpixels SP can be disposed in the display area DA of the display panel 110. The plurality of subpixels SP can be disposed in the normal area NA and the optical area OA included in the display area DA.

Each of the plurality of subpixels SP can include a light emitting element ED and a subpixel circuit SPC configured to drive the light emitting element ED.

The subpixel circuit SPC can include a driving transistor DT for driving the light emitting element ED, a scan transistor ST for transferring the data voltage VDATA to the driving transistor DT, and a storage capacitor Cst for maintaining a constant voltage during one frame.

The driving transistor DT can include a first node N1, a second node N2, and a third node N3. The first node N1 can be a node connected to the light emitting element ED. The second node N2 can be a node connected to the scan transistor ST. The third node N3 can be a node connected to the driving voltage line VDDL. The first node N1 can be electrically connected to the pixel electrode PE of the light emitting element ED. A data voltage VDATA can be applied to the second node N2. A driving voltage VDD can be applied to the third node N3. The first node N1 can be the source node or the drain node, the second node N2 can be the gate node, and the third node N3 can be the drain node or the source node. For convenience of description, described below is an example in which the first node N1 in the driving transistor DT is the source node, the second node N2 is the gate node, and the third node N3 is the drain node.

The light emitting element ED can include a pixel electrode PE, an intermediate layer EL, and a common electrode CE. The pixel electrode PE can be an electrode disposed in each subpixel SP. For example, the pixel electrode PE can be electrically connected directly or indirectly (through another transistor) to the first node N1 of the driving transistor DT of each subpixel SP. The common electrode CE can be an electrode commonly disposed in a plurality of subpixels SP. For example, the common electrode CE can receive a base voltage VSS, which is a type of common driving voltage, through a base voltage line VSSL. For example, the pixel electrode PE can be an anode electrode, and the common electrode CE can be a cathode electrode. Conversely, the pixel electrode PE can be a cathode electrode, and the common electrode CE can be an anode electrode. For convenience of description, it is assumed below that the pixel electrode PE is an anode electrode, and the common electrode CE is a cathode electrode.

The intermediate layer EL can include a light emitting layer EML and a common intermediate layer EL_COM.

The light emitting layer EML can be disposed in the emission area of each of the plurality of subpixels SP. For example, the light emitting layer EML can be disposed only in each of the subpixels SP. As another example, the light emitting layer EML can be commonly disposed across the plurality of subpixels SP. As another example, the light emitting layer EML can be disposed only in the emission area. As another example, the light emitting layer EML can be disposed in both the emission area and the non-emission area.

The common intermediate layer EL_COM can be commonly disposed over the plurality of subpixels SP. The common intermediate layer EL_COM can be commonly disposed across a plurality of emission areas EA and non-emission areas.

The common intermediate layer EL_COM can include a first common intermediate layer COM1 and a second common intermediate layer COM2. The first common intermediate layer COM1 can be disposed between the pixel electrode PE and the light emitting layer EML and can include at least one layer (e.g., an organic layer). The second common intermediate layer COM2 can be disposed between the light emitting layer EML and the common electrode CE and can include at least one layer (e.g., an organic layer).

For example, the first common intermediate layer COM1 can include a hole injection layer HIL and a hole transport layer HTL. The second common intermediate layer COM2 can include an electron transport layer ETL and an electron injection layer EIL. The hole injection layer HIL can inject holes from the pixel electrode PE to the hole transport layer HTL, and the hole transport layer HTL can transport holes to the light emitting layer EML. The electron injection layer EIL can inject electrons from the common electrode CE to the electron transport layer ETL, and the electron transport layer ETL can transport electrons to the light emitting layer EML. However, in addition to the hole injection layer HIL, hole transport layer HTL, electron injection layer EIL, and electron transport layer ETL described above, other layers can be further disposed in the first common intermediate layer COM1 and the second common intermediate layer COM2. This can follow the OLED device structure that is typically being developed.

Each light emitting element ED can include portions where the pixel electrode PE, the light emitting layer EML in the intermediate layer EL, and the common electrode CE overlap. A predetermined emission area EA can be formed by the light emitting element ED. For example, the emission area EA can be defined as an area where the pixel electrode PE, the light emitting layer EML of the intermediate layer EL, and the common electrode CE overlap. For example, the light emitting element ED can be an organic material-based organic light emitting diode (OLED), an inorganic material-based inorganic light emitting diode, or a quantum dot light emitting element. When the light emitting element ED is an organic light emitting diode, the intermediate layer EL of the light emitting element ED can include an organic layer including an organic material.

The scan transistor ST can be controlled to be turned on and off by the scan signal SC, which is a kind of gate signal applied through the scan signal line SCL, which is a type of the gate line GL, and be electrically connected between the second node N2 of the driving transistor DT and the data line DL.

The storage capacitor Cst can be electrically connected between the first node N1 and second node N2 of the driving transistor DT.

As illustrated in FIG. 3, the subpixel circuit SPC can have a 2T (Transistor) 1C (Capacitor) structure including two transistors DT and ST and one capacitor Cst. In some cases, the subpixel circuit SPC can further include one or more transistors or can further include one or more capacitors.

The capacitor Cst can be an external capacitor intentionally designed to be outside the driving transistor DT, but not a parasite capacitor (e.g., Cgs or Cgd) which is an internal capacitor that can be present between the first node N1 and the second node N2 of the driving transistor DT. Each of the driving transistor DT and the scan transistor ST can be an n-type transistor or a p-type transistor.

Since the circuit elements (particularly, the light emitting element ED implemented as an organic light emitting diode (OLED) containing an organic material) in each subpixel SP are vulnerable to external moisture or oxygen, an encapsulation layer 500 can be disposed on the display panel 110 to prevent penetration of external moisture or oxygen into the circuit elements (particularly, the light emitting element ED). The encapsulation layer 500 can be disposed to cover the light emitting elements ED.

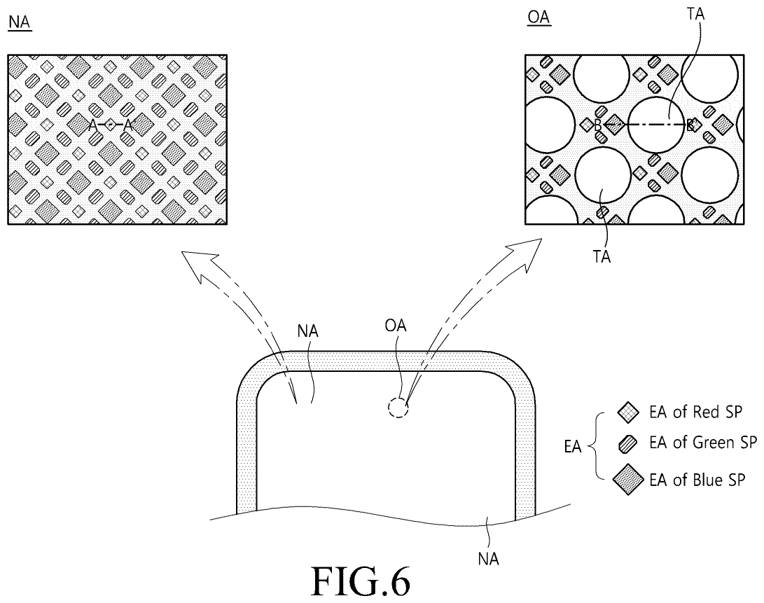

FIG. 6 is a view illustrating an arrangement of subpixels SP in two areas NA and OA included in a display area DA of a display panel 110 according to embodiments of the disclosure.

Referring to FIG. 6, a plurality of subpixels SP can be disposed in each of the normal area NA and the optical area OA included in the display area DA.

For example, the plurality of subpixels SP can include a red subpixel Red SP emitting red light, a green subpixel Green SP emitting green light, and a blue subpixel Blue SP emitting blue light.

Accordingly, each of the normal area NA and the optical area OA can include emission areas EA of the red subpixels Red SP, emission areas EA of the green subpixels Green SP, and emission areas EA of the blue subpixels Blue SP.

The normal area NA may not include a light transmission structure, but can include emission areas EA.

However, the optical area OA should not only include the emission areas EA, but also include a light transmission structure.

Thus, the optical area OA can include emission areas EA and a transmissive area TA.

The emission areas EA and the transmissive area TA can be distinguished based on whether they can transmit light. In other words, the emission areas EA can be areas through which light cannot pass, and the transmissive area TA can be areas through which light can pass.

Further, the emission areas EA and the transmissive area TA can be distinguished depending on the presence or absence of a specific metal layer CE. For example, a common electrode CE can be formed in the emission areas EA, and a common electrode CE may not be formed in the transmissive area TA. A light shield layer can be formed in the emission areas EA, and a light shield layer may not be formed in the transmissive area TA.

Since the optical area OA includes the transmissive area TA, the optical area OA is an area through which light can be transmitted.

Further, in embodiments of the disclosure, the transmissive area TA can also be referred to as a transparent area, and the transmittance can also be referred to as transparency.

Further, in embodiments of the disclosure, it is assumed that the optical area OA is positioned at the upper end of the display area DA of the display panel 110.

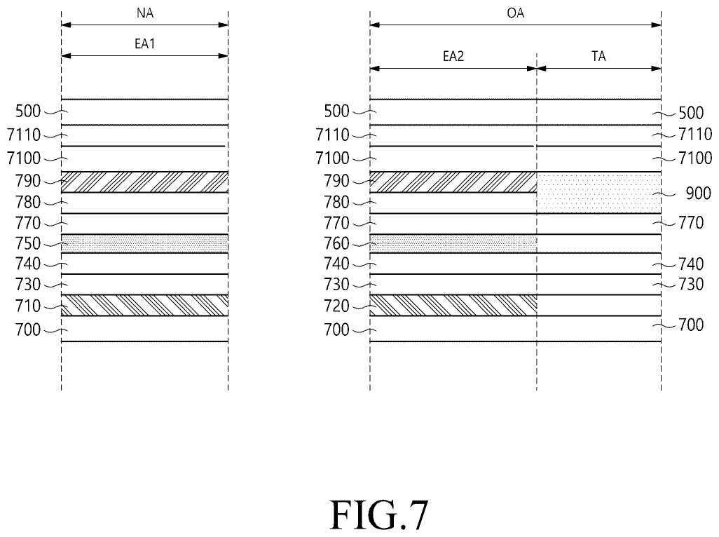

FIG. 7 is a schematic cross-sectional view illustrating a portion of a first emission area EA1 disposed in a normal area NA and a schematic cross-sectional view illustrating a portion of a second emission area EA2 and a transmissive area TA disposed in an optical area OA as illustrated in FIG. 6.

A cross-sectional view of the normal area NA is schematically described with reference to FIG. 7.

Referring to FIG. 7, the normal area NA can include a first emission area EA1. A planarization layer 700 can be disposed in the first emission area EA1.

A first anode electrode 710 can be disposed on the planarization layer 700 of the first emission area EA1. Here, the first anode electrode 710 can have functionally the same configuration as the pixel electrode PE described above with reference to FIG. 5. A hole injection layer 730 can be disposed on the first anode electrode 710. A hole transport layer 740 can be disposed on the hole injection layer 730. A first light emitting layer 750 can be disposed on the hole transport layer 740. An electron transport layer 770 can be disposed on the first light emitting layer 750. An electron injection layer 780 can be disposed on the electron transport layer 770. A first cathode electrode 790 can be disposed on the electron injection layer 780. Here, the first cathode electrode 790 can have functionally the same configuration as the common electrode CE described above with reference to FIG. 5.

The first anode electrode 710, the hole injection layer 730, the hole transport layer 740, the first light emitting layer 750, the electron transport layer 770, the electron injection layer 780, and the first cathode electrode 790 can constitute one light emitting element ED.

Here, the first anode electrode 710, the hole injection layer 730, the hole transport layer 740, the first light emitting layer 750, the electron transport layer 770, the electron injection layer 780, and the first cathode electrode 790 can have functionally the same configuration as the pixel electrode PE, the hole injection layer HIL, the hole transport layer HTL, the light emitting layer EML, the electron injection layer EIL, and the common electrode CE described above with reference to FIG. 5.

A first capping layer 7100 can be disposed on the first cathode electrode 790 of the first emission area EA1. A second capping layer 7110 can be disposed on the first capping layer 7100. The first capping layer 7100 and the second capping layer 7110 can be formed together during an organic material deposition process, and the material thereof can be an organic material or an inorganic material.

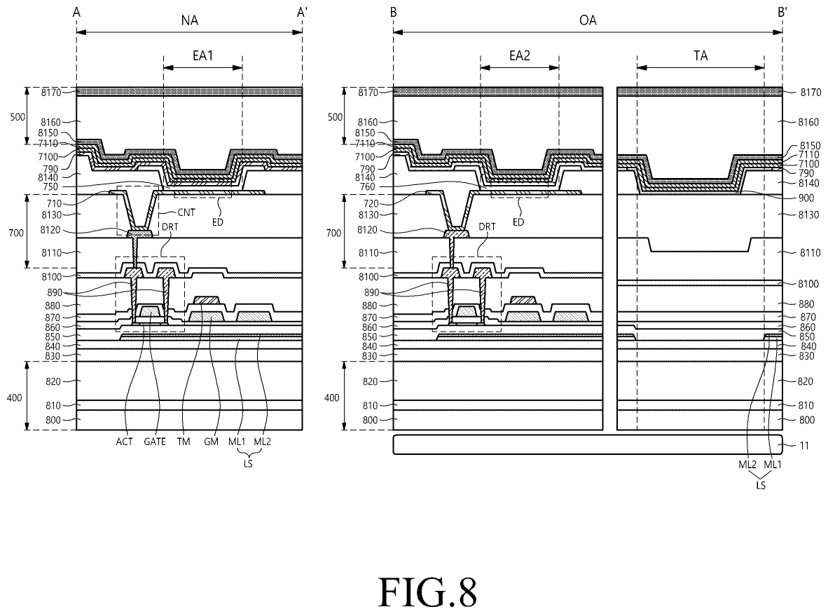

An encapsulation layer 500 can be disposed on the second capping layer 7110. The encapsulation layer 500 can have a single layer structure or a multilayer structure. A specific example is described in the cross-sectional view of FIG. 8.

Next, the optical area OA can include a second emission area EA2 and a transmissive area TA.

Referring to FIG. 7, the second emission area EA2 can have the same configuration as the first emission area EA1 of the normal area NA described above. However, a second anode electrode 720 and a second light emitting layer 760 distinguished from the first anode electrode 710 and the first light emitting layer 750 included in the first emission area EA1 can be included.

Accordingly, the planarization layer 700 can be disposed in the second emission area EA2, and the second anode electrode 720, which is a component separate from the first anode electrode 710, can be disposed on the planarization layer 700. A hole injection layer 730 can be disposed on the second anode electrode 720. A hole transport layer 740 can be disposed on the hole injection layer 730. A second light emitting layer 760 which is a component separate from the first light emitting layer 750 can be disposed on the hole transport layer 740. An electron transport layer 770 can be disposed on the second light emitting layer 760. An electron injection layer 780 can be disposed on the electron transport layer 770. A first cathode electrode 790 can be disposed on the electron injection layer 780.

The second anode electrode 720, the hole injection layer 730, the hole transport layer 740, the second light emitting layer 760, the electron transport layer 770, the electron injection layer 780, and the first cathode electrode 790 described above can constitute one light emitting element ED, which can be a light emitting element ED distinguished from the light emitting element ED included in the first emission area EA1.

Here, the second anode electrode 720, the hole injection layer 730, the hole transport layer 740, the second light emitting layer 760, the electron transport layer 770, the electron injection layer 780, and the first cathode electrode 790 can have functionally the same configuration as the pixel electrode PE, the hole injection layer HIL, the hole transport layer HTL, the light emitting layer EML, the electron injection layer EIL, and the common electrode CE described above with reference to FIG. 5.

A first capping layer 7100 can be disposed on the first cathode electrode 790 of the second emission area EA2. A second capping layer 7110 can be disposed on the first capping layer 7100. An encapsulation layer 500 can be disposed on the second capping layer 7110.

Next, a planarization layer 700 can be disposed in the transmissive area TA. A hole injection layer 730 can be disposed on the planarization layer 700 in the transmissive area TA. A hole transport layer 740 can be disposed on the hole injection layer 730. An electron transport layer 770 can be disposed on the hole transport layer 740. The first patterning layer 900 can be disposed on the electron transport layer 770.

The first patterning layer 900 can be formed of a carbon organic material such as 3-(biphenyl-4-yl)-5-(4-tert-butylphenyl)-4-phenyl-4H-1,2,4-triazole (TAZ), but this disclosure is not limited to it. As the first patterning layer 900 has a low-adhesion characteristic in which the surface energy of the material itself is low or interfacial energy between the metal and the patterning layer is high, the probability of desorption of the metal on the surface of the first patterning layer 900 during metal deposition is significantly increased, and metal nucleation does not occur. In other words, the first patterning layer 900 can serve to prevent the first cathode electrode 790 from being formed in the transmissive area TA. Thus, a cathode hole can be formed in the transmissive area TA of the optical area OA.

Therefore, the first cathode electrode 790 may not be disposed on the first patterning layer 900, but the first capping layer 7100 can be disposed. A second capping layer 7110 can be disposed on the first capping layer 7100. An encapsulation layer 500 can be disposed on the second capping layer 7110.

In other words, unlike the first emission area EA1 and the second emission area EA2, the pixel electrode PE, the light emitting layer EML, and the first cathode electrode 790 may not be disposed in the transmissive area TA. However, the light emitting layer EML can be disposed between the hole transport layer 740 and the electron transport layer 770 in the transmissive area TA.

Hereinafter, the overall cross-sectional view between the substrate 400 and the encapsulation layer 500, rather than the schematic cross-sectional structure of the display panel 110, is described in connection with FIG. 8.

FIG. 8 is a cross-sectional view taken along dashed line A-A′ of the normal area NA of FIG. 6 and along dashed line B-B′ of the optical area OA.

However, in FIG. 8, for convenience of description, illustrations of the hole injection layer 730, the hole transport layer 740, the electron transport layer 770, and the electron injection layer 780 described above with reference to FIG. 7 are omitted. The omitted components can be disposed in the same manner as the structure of the light emitting element ED of the conventional organic light emitting diode OLED.

The cross-sectional structure of the normal area NA is described with reference to FIG. 8. The substrate 400 can include a first substrate 800, an interlayer insulation film 810, and a second substrate 820. The interlayer insulation film 810 can be positioned between the first substrate 800 and the second substrate 820. By configuring the substrate 400 with the first substrate 800, the interlayer insulation film 810 and the second substrate 820, it is possible to prevent moisture penetration. For example, the first substrate 800 and the second substrate 820 can be polyimide (PI) substrates. The first substrate 800 can be referred to as a primary PI substrate, and the second substrate 820 can be referred to as a secondary PI substrate.

Referring to FIG. 8, on the substrate 400, various patterns ACT, 890, and GATE for forming a transistor, such as a driving transistor DRT, various insulation films 830, 840, 850, 860, 870, 880, and 8100, and various metal patterns TM, GM, ML1, and ML2 can be disposed.

A multi-buffer layer 830 can be disposed on the second substrate 820. A first active buffer layer 840 can be disposed on the multi-buffer layer 830.

A first metal layer ML1 and a second metal layer ML2 can be disposed on the first active buffer layer 840. The first metal layer ML1 and the second metal layer ML2 can be a light shield layer LS for shielding light.

A second active buffer layer 850 can be disposed on the first metal layer ML1 and the second metal layer ML2. An active layer ACT of the driving transistor DRT can be disposed on the second active buffer layer 850.

A gate insulation film 860 can be disposed while covering the active layer ACT.

A gate electrode GATE of the driving transistor DRT can be disposed on the gate insulation film 860. In this case, in a position different from the position where the driving transistor DRT is formed, a gate material layer GM, together with the gate electrode GATE of the driving transistor DRT, can be disposed on the gate insulation film 860.

The first interlayer insulation film 870 can be disposed while covering the gate electrode GATE and the gate material layer GM. A metal pattern TM can be disposed on the first interlayer insulation film 870. The metal pattern TM can be located in a position different from the position where the driving transistor DRT is formed. The second interlayer insulation film 880 can be disposed while covering the metal pattern TM on the first interlayer insulation film 870.

Two first source-drain electrode patterns 890 can be disposed on the second interlayer insulation film 880. One of the two first source-drain electrode patterns 890 is the source node of the driving transistor DRT, and the other is the drain node of the driving transistor DRT. The two first source-drain electrode patterns 890 can be electrically connected with the two opposite sides of the active layer ACT through the contact hole of the second interlayer insulation film 880, the first interlayer insulation film 870, and the gate insulation film 860.

A portion of the active layer ACT overlapping the gate electrode GATE is a channel area. One of the two first source-drain electrode patterns 890 can be connected to one side of the channel area in the active layer ACT, and the other one of the two first source-drain electrode patterns 890 can be connected to the other side of the channel area in the active layer ACT.

A passivation layer 8100 is disposed while covering the two first source-drain electrode patterns 890. A planarization layer 700 can be disposed on the passivation layer 8100. The planarization layer 700 can include a first planarization layer 8110 and a second planarization layer 8130.

The first planarization layer 8110 can be disposed on the passivation layer 8100.

A second source-drain electrode pattern 8120 can be disposed on the first planarization layer 8110. The second source-drain electrode pattern 8120 can be connected with one of the two first source-drain electrode patterns 890 (corresponding to the first node N1 of the driving transistor DRT in the subpixel SP of FIG. 5) through the contact hole of the first planarization layer 8110.

The second planarization layer 8130 can be disposed while covering the second source-drain electrode pattern 8120.

A light emitting element ED can be disposed on the second planarization layer 8130. In the stacked structure of the light emitting element ED, the first anode electrode 710 can be disposed on the second planarization layer 8130. The first anode electrode 710 can be electrically connected to the second source-drain electrode pattern 8120 through the contact hole CNT of the second planarization layer 8130.

The bank 8140 can be disposed while covering a portion of the first anode electrode 710. A portion of the bank 8140 corresponding to the first emission area EA1 of the subpixel SP can be opened.

A portion of the first anode electrode 710 can be exposed through an opening (open portion) of the bank 8140. A first light emitting layer 750 can be positioned on a side surface of the bank 8140 and the opening (open portion) of the bank 8140. The whole or part of the first light emitting layer 750 can be positioned between adjacent banks 8140. Here, the first light emitting layer 750 can have the same configuration as the light emitting layer EML described above in connection with FIG. 5. In the opening of the bank 8140, the first light emitting layer 750 can contact the first anode electrode 710.

A first cathode electrode 790 can be disposed on the first light emitting layer 750 and the bank 8140. The first cathode electrode 790 can be disposed over the entire surface of the normal area NA.

A light emitting element ED can be formed by the first anode electrode 710, the first light emitting layer 750, and the first cathode electrode 790.

A first capping layer 7100 can be disposed on the first cathode electrode 790. A second capping layer 7110 can be disposed on the first capping layer 7100. In this case, the refractive index of the first capping layer 7100 can be higher than the refractive index of the second capping layer 7110. For example, the refractive index of the first capping layer 7100 can be 1.8 or more. The refractive index of the second capping layer 7110 can be lower than the refractive index of the first capping layer 7100. For example, the refractive index of the second capping layer 7110 can be 1.4.

By disposing the first capping layer 7100 and the second capping layer 7110 having different refractive indices on the first cathode electrode 790, a micro cavity effect can be induced through a light reflection occurring at the interface of each layer. Accordingly, the luminance of light output from the area in which the first capping layer 7100 and the second capping layer 7110 are disposed can be increased to enhance luminous efficiency.

Meanwhile, in FIG. 8, only the first capping layer 7100 and the second capping layer 7110 are illustrated, but the disclosure is not limited thereto. For example, a third capping layer and a fourth capping layer having different refractive indices can be additionally disposed on the second capping layer 7110. However, in the disclosure, for convenience of description, an example is described in which the first capping layer 7100 and the second capping layer 7110 are disposed.

The encapsulation layer 500 can be disposed on the second capping layer 7110. The encapsulation layer 500 can have a single layer structure or a multilayer structure. For example, as illustrated in FIG. 8, the encapsulation layer 500 can include a first encapsulation layer 8150, a second encapsulation layer 8160, and a third encapsulation layer 8170.

For example, the first encapsulation layer 8150 and the third encapsulation layer 8170 can be inorganic films, and the second encapsulation layer 8160 can be organic films. Among the first encapsulation layer 8150, the second encapsulation layer 8160, and the third encapsulation layer 8170, the second encapsulation layer 8160 can be the thickest and can serve as a planarization layer.

The first encapsulation layer 8150 can be disposed on the second capping layer 7110 and can be disposed closest to the second capping layer 7100. The first encapsulation layer 8150 can be formed of an inorganic insulating material capable of low temperature deposition. For example, the first encapsulation layer 8150 can be formed of silicon nitride (SiNx), silicon oxide (SiOx), silicon oxynitride (SiON), or aluminum oxide (Al2O3). Since the first encapsulation layer 8150 is deposited in a low-temperature atmosphere, the first encapsulation layer 8150 can prevent the first light emitting layer 750 including an organic material vulnerable to a high-temperature atmosphere from being damaged during the deposition process.

The second encapsulation layer 8160 can be formed with an area smaller than that of the first encapsulation layer 8150. In this case, the second encapsulation layer 8160 can be formed to expose two opposite ends of the first encapsulation layer 8150. The second encapsulation layer 8160 can serve as a buffer to relieve stress between layers due to bending of the display device 100, and can also serve to enhance planarization performance. For example, the second encapsulation layer 8160 can be an acrylic resin, an epoxy resin, polyimide, polyethylene, silicon oxycarbon (SiOC), or the like, and can be formed of an organic insulating material. For example, the second encapsulation layer 8160 can be formed through an inkjet method.

The third encapsulation layer 8170 can be formed on the substrate 400 on which the second encapsulation layer 8160 is formed to cover the upper surface and the side surface of each of the second encapsulation layer 8160 and the first encapsulation layer 8150. The third encapsulation layer 8170 can minimize or block external moisture or oxygen from penetrating into the first encapsulation layer 8150 and the second encapsulation layer 8160. For example, the third encapsulation layer 8170 is formed of an inorganic insulating material, such as silicon nitride (SiNx), silicon oxide (SiOx), silicon oxynitride (SiON), or aluminum oxide (Al2O3).

Next, a stacked structure for the optical area OA is described with reference to FIG. 8.

Referring to FIG. 8, the second emission area EA2 in the optical area OA performs the same function as the first emission area EA1 in the normal area NA, but can include a second anode electrode 720 and a second light emitting layer 760 that are physically separate components. Except for the second anode electrode 720 and the second light emitting layer 760 of the second emission area EA2, the remaining components can have the same stacked structure as that of the first emission area EA1. Therefore, the stacked structure of the transmissive area TA in the optical area OA is described below in detail.

The first cathode electrode 790 is disposed in the first emission area EA1 and the second emission area EA2 included in the normal area NA and the optical area OA, but the first cathode electrode 790 may not be disposed in the transmissive area TA in the optical area OA. In other words, the transmissive area TA in the optical area OA can correspond to the opening of the first cathode electrode 790.

To form an opening of the first cathode electrode 790 in the transmissive area TA, a first patterning layer 900 can be disposed in the transmissive area TA. If the first patterning layer 900 is disposed in the area corresponding to the transmissive area TA before the first cathode electrode 790 is disposed on the second light emitting layer 760, when the first cathode electrode 790 is disposed later, it can be disposed in an area other than the first patterning layer 900. Therefore, the first patterning layer 900 can be disposed on the planarization layer 700 and the bank 8140 in the area corresponding to the transmissive area TA. As another example, when the light emitting layer is disposed in the transmissive area TA, the first patterning layer 900 can be disposed on the light emitting layer.

Further, the light shield layer LS including at least one of the first and second metal layers ML1 and ML2 is disposed in the first emission area EA1 included in the normal area NA and the second emission area EA2 included in the optical area OA, but the light shield layer LS may not be disposed in the transmissive area TA in the optical area OA. In other words, the transmissive area TA in the optical area OA can correspond to the opening of the light shield layer LS.

The substrate 400 and various insulation films 830, 840, 850, 860, 870, 880, and 8100 disposed in the first emission area EA1 included in the normal area NA and the second emission area EA2 included in the optical area OA can be equally disposed in the transmissive area TA. In addition to the insulating material in the first emission area EA1 and the second emission area EA2, a material layer (e.g., a metal material layer, a semiconductor layer, etc.) having electrical characteristics may not be disposed in the transmissive area TA in the optical area OA.

For example, referring to FIG. 8, the metal material layers ML1, ML2, GATE, GM, TM, 890, and 8120 and the semiconductor layer ACT related to the transistor may not be disposed in the transmissive area TA in the optical area OA.

Further, the first anode electrode 710, the second anode electrode 720 and the first cathode electrode 790 included in the light emitting element ED may not be disposed in the transmissive area TA in the optical area OA. However, the first emission layer 750 and the second emission layer 760 may or may not be disposed in the transmissive area TA in the optical area OA.

Therefore, light transmittance of the transmissive area TA in the optical area OA can be provided by not disposing a material layer (e.g., a metal material layer, a semiconductor layer, etc.) having electrical characteristics in transmissive area TA of the optical area OA. Therefore, the first optical electronic device 11 can receive light transmitted through the transmissive area TA and perform the corresponding function (e.g., sensing the approach of an object or human body, detecting external illuminance, etc.).

Meanwhile, by forming the transmissive area TA to increase the transmittance of the optical area OA, the number of subpixels SP per unit area disposed in the optical area OA can be decreased. Accordingly, a luminance deviation can occur due to a difference in the number of subpixels SP between the normal area NA and the optical area OA. The luminance deviation between the normal area NA and the optical area OA can lead to a deterioration in aesthetic completeness and impose restrictions on the design of the front portion of display panel 110.

In an embodiment of the disclosure, the issue of luminance deviation between the above-described normal area NA and the optical area OA can be addressed by disposing the second cathode electrode 920 in the optical area OA.

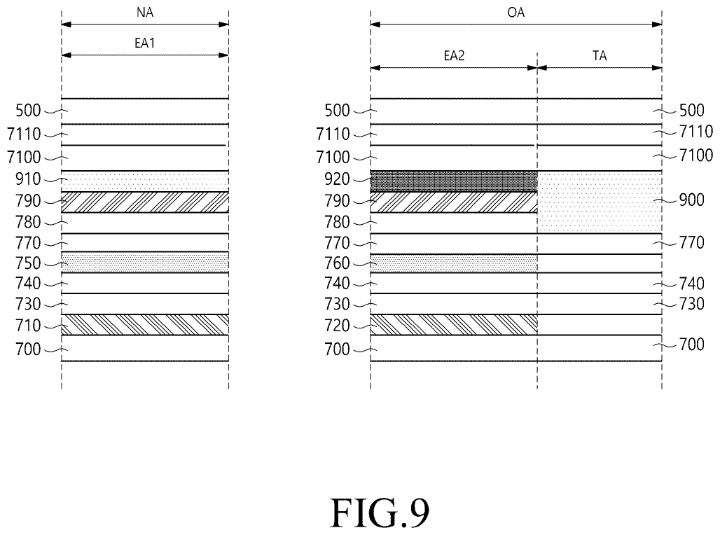

FIG. 9 is a schematic cross-sectional view for each area of a display panel 110 when a second cathode electrode 920 is disposed in a second emission area EA2 according to embodiments of the disclosure.

A cross-sectional view of the normal area NA is schematically described with reference to FIG. 9.

Referring to FIG. 9, the normal area NA can include a first emission area EA1. A planarization layer 700 can be disposed in the first emission area EA1.

A first anode electrode 710 can be disposed on the planarization layer 700 of the first emission area EA1. Here, the first anode electrode 710 can have functionally the same configuration as the pixel electrode PE described above with reference to FIG. 5. A hole injection layer 730 can be disposed on the first anode electrode 710. A hole transport layer 740 can be disposed on the hole injection layer 730. A first light emitting layer 750 can be disposed on the hole transport layer 740. An electron transport layer 770 can be disposed on the first light emitting layer 750. An electron injection layer 780 can be disposed on the electron transport layer 770. A first cathode electrode 790 can be disposed on the electron injection layer 780. Here, the first cathode electrode 790 can have functionally the same configuration as the common electrode CE described above with reference to FIG. 5.

The first anode electrode 710, the hole injection layer 730, the hole transport layer 740, the first light emitting layer 750, the electron transport layer 770, the electron injection layer 780, and the first cathode electrode 790 can constitute one light emitting element ED.

Here, the first anode electrode 710, the hole injection layer 730, the hole transport layer 740, the first light emitting layer 750, the electron transport layer 770, the electron injection layer 780, and the first cathode electrode 790 can have functionally the same configuration as the pixel electrode PE, the hole injection layer HIL, the hole transport layer HTL, the light emitting layer EML, the electron injection layer EIL, and the common electrode CE described above with reference to FIG. 5.

In this case, the electron injection layer 780 can include a metal material, and can include an alkali metal such as lithium fluoride (LiF).

A second patterning layer 910 can be disposed on the first cathode electrode 790 of the first emission area EA1. The second patterning layer 910 can have the same characteristics as the first patterning layer 900 described above with reference to FIG. 7. For example, the second patterning layer 910 can have a low-adhesion property in which the surface energy of the material itself is low or the interfacial energy between the metal and the patterning layer is high. Therefore, the probability of desorption of metal on the surface of the second patterning layer 910 during metal deposition increases significantly, and metal nucleation does not occur. In other words, the second patterning layer 910 can prevent the second cathode electrode 920 to be described below from being formed on the second patterning layer 910 of the first emission area EA1.

A first capping layer 7100 can be disposed on the second patterning layer 910 of the first emission area EA1. A second capping layer 7110 can be disposed on the first capping layer 7100. The first capping layer 7100 and the second capping layer 7110 can be formed together during an organic material deposition process, and the material thereof can be an organic material or an inorganic material.

An encapsulation layer 500 can be disposed on the second capping layer 7110. The encapsulation layer 500 can have a single layer structure or a multilayer structure.

Next, the optical area OA can include a second emission area EA2 and a transmissive area TA.

Referring to FIG. 9, the second emission area EA2 can have a structure similar to that of the first emission area EA1 described above. In the first emission area EA1, the second patterning layer 910 is disposed between the first cathode electrode 790 and the first capping layer 7100, but in the second emission area EA2, the second cathode electrode 920 is disposed between the first cathode electrode 790 and the first capping layer 7100.

Accordingly, the planarization layer 700 can be disposed in the second emission area EA2, and the second anode electrode 720, which is a component separate from the first anode electrode 710, can be disposed on the planarization layer 700. A hole injection layer 730 can be disposed on the second anode electrode 720. A hole transport layer 740 can be disposed on the hole injection layer 730. A second light emitting layer 760 which is a component separate from the first light emitting layer 750 can be disposed on the hole transport layer 740. An electron transport layer 770 can be disposed on the second light emitting layer 760. An electron injection layer 780 can be disposed on the electron transport layer 770. A first cathode electrode 790 can be disposed on the electron injection layer 780.

In this case, the electron injection layer 780 can include a metal material, and can include an alkali metal such as lithium fluoride (LiF).

The second anode electrode 720, the hole injection layer 730, the hole transport layer 740, the second light emitting layer 760, the electron transport layer 770, the electron injection layer 780, and the first cathode electrode 790 described above can constitute one light emitting element ED, which can be a light emitting element ED distinguished from the light emitting element ED included in the first emission area EA1.

Here, the second anode electrode 720, the hole injection layer 730, the hole transport layer 740, the second light emitting layer 760, the electron transport layer 770, the electron injection layer 780, and the first cathode electrode 790 can have functionally the same configuration as the pixel electrode PE, the hole injection layer HIL, the hole transport layer HTL, the light emitting layer EML, the electron injection layer EIL, and the common electrode CE described above with reference to FIG. 5.

A second cathode electrode 920 can be disposed on the first cathode electrode 790 of the second emission area EA2. As the second cathode electrode 920 is disposed on the first cathode electrode 790, a micro cavity (resonance) effect can be induced through a light reflection occurring at the interface of each layer. Accordingly, it is possible to increase the luminance of the second emission area EA2. In order to induce a microcavity effect between the first cathode electrode 790 and the second cathode electrode 920, the first cathode electrode 790 and the second cathode electrode 920 can be disposed to have different refractive indices. Further, the thickness of the second cathode electrode 920 can be variously adjusted. For example, the thickness of the second cathode electrode 920 can be selected between 1 nm and 4 nm. However, the thickness of the second cathode electrode 920 is not limited thereto.

A first capping layer 7100 can be disposed on the second cathode electrode 920 in the second emission area EA2. A second capping layer 7110 can be disposed on the first capping layer 7100. The first capping layer 7100 and the second capping layer 7110 can be disposed to have different refractive indices.

Therefore, the first cathode electrode 790, the second cathode electrode 920, the first capping layer 7100, and the second capping layer 7110 of the second emission area EA2 described above can be disposed to have different refractive indices to induce a microcavity effect. Therefore, the luminous efficiency of light output from the second emission area EA2 can be increased.

For example, the first cathode electrode 790 can have a refractive index larger than or equal to 1.8. The second cathode electrode 920 can have a refractive index of 1.4. The first capping layer 7100 can have a refractive index larger than or equal to 1.8. The second capping layer 7110 can have a refractive index of 1.4. Thus, light output from the second light emitting layer 760 of the second emission area EA2 can be amplified by the micro cavity effect while passing through the first cathode electrode 790, the second cathode electrode 920, the first capping layer 7100, and the second capping layer 7110 having different refractive indices.

However, this is merely an example for description, and the disclosure is not limited to the above-described structure. For example, the first cathode electrode 790, the second cathode electrode 920, the first capping layer 7100, and the second capping layer 7110 can have refractive indices different from those described above. Further, a third capping layer and a fourth capping layer can be further disposed on the second capping layer 7110.

An encapsulation layer 500 can be disposed on the second capping layer 7110.

Next, referring to FIG. 9, a planarization layer 700 can be disposed in the transmissive area TA. A hole injection layer 730 can be disposed on the planarization layer 700 in the transmissive area TA. A hole transport layer 740 can be disposed on the hole injection layer 730. An electron transport layer 770 can be disposed on the hole transport layer 740. The first patterning layer 900 can be disposed on the electron transport layer 770.

The first patterning layer 900 can have the same characteristics as the second patterning layer 910 disposed in the first emission area EA1. The first patterning layer 900 and the second patterning layer 910 can be formed of the same material. Further, the first patterning layer 900 and the second patterning layer 910 can be formed of different materials.

As the first patterning layer 900 is disposed in the transmissive area TA according to an embodiment of the disclosure, the first cathode electrode 790 and the second cathode electrode 920 may not be disposed on the first patterning layer 900 in the transmissive area TA. In other words, the first patterning layer 900 can serve to prevent the formation of the first cathode electrode 790 and the second cathode electrode 920 in the transmissive area TA. Therefore, the transmission of light to the transmissive area TA of the optical area OA can be facilitated.

The first cathode electrode 790 and the second cathode electrode 920 may not be disposed on the first patterning layer 900 of the transmissive area TA, but the first capping layer 7100 can be disposed. A second capping layer 7110 can be disposed on the first capping layer 7100. An encapsulation layer 500 can be disposed on the second capping layer 7110.

The first anode electrode 710, the second anode electrode 720, the first light emitting layer 750, the second light emitting layer 760, the first cathode electrode 790, and the second cathode electrode 920 may not be disposed in the transmissive area TA of the optical area OA. However, the first light emitting layer 750 and the second light emitting layer 760 can be disposed in the transmissive area TA.

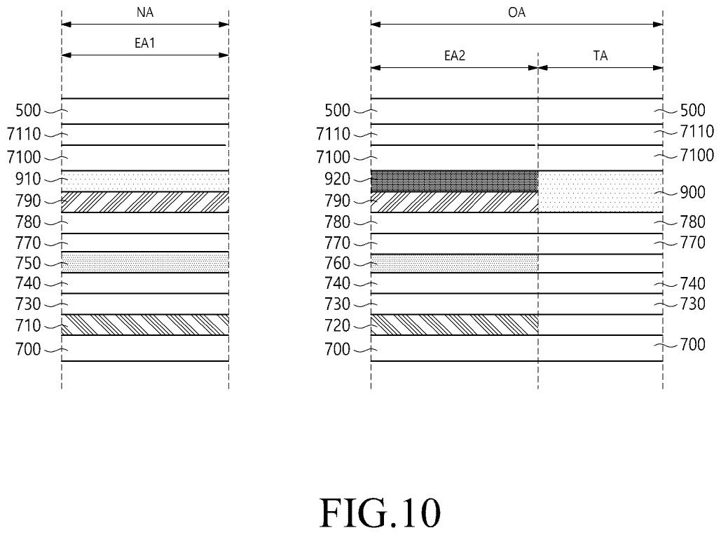

Meanwhile, as described above, the first patterning layer 900 can be disposed on the electron transport layer 770, but can also be disposed on the electron injection layer 780. A schematic cross-sectional view illustrating a case where the first patterning layer 900 is disposed on the electron injection layer 780 is described with reference to FIG. 10.

FIG. 10 is a schematic cross-sectional view for each area of a display panel 110 when a first patterning layer 900 is disposed on an electron injection layer 780 in an transmissive area TA according to embodiments of the disclosure.

Referring to FIG. 10, the structures of the first emission area EA1 of the normal area NA and the second emission area EA2 of the optical area OA can be the same as those of the first emission area EA1 and the second emission area EA2 illustrated in FIG. 9.

A planarization layer 700 can be disposed in the transmissive area TA of the optical area OA. A hole injection layer 730 can be disposed on the planarization layer 700. A hole transport layer 740 can be disposed on the hole injection layer 730. An electron transport layer 770 can be disposed on the hole transport layer 740.

In the transmissive area TA in the schematic cross-sectional view of the display panel 110 illustrated in FIG. 9, the first patterning layer 900 is disposed on the electron transport layer 770, but in the transmissive area TA in the schematic cross-sectional view of the display panel 110 illustrated in FIG. 10, the electron injection layer 780 can be disposed on the electron transport layer 770, and the first patterning layer 900 can be disposed on the electron injection layer 780.

In this case, the electron injection layer 780 can include a metal material, and can include an alkali metal such as lithium fluoride (LiF).

Referring to FIG. 10, a first capping layer 7100 can be disposed on the first patterning layer 900. A second capping layer 7110 can be disposed on the first capping layer 7100. The encapsulation layer 500 can be disposed on the second capping layer 7110.

In the structure of the transmissive area TA illustrated in FIG. 10, like the structure of the transmissive area TA illustrated in FIG. 9, as the first patterning layer 900 is disposed, the first cathode electrode 790 and the second cathode electrode 920 may not be disposed on the first patterning layer 900 of the transmissive area TA. In other words, the first patterning layer 900 can serve to prevent the formation of the first cathode electrode 790 and the second cathode electrode 920 in the transmissive area TA. Therefore, the transmission of light to the transmissive area TA of the optical area OA can be facilitated.

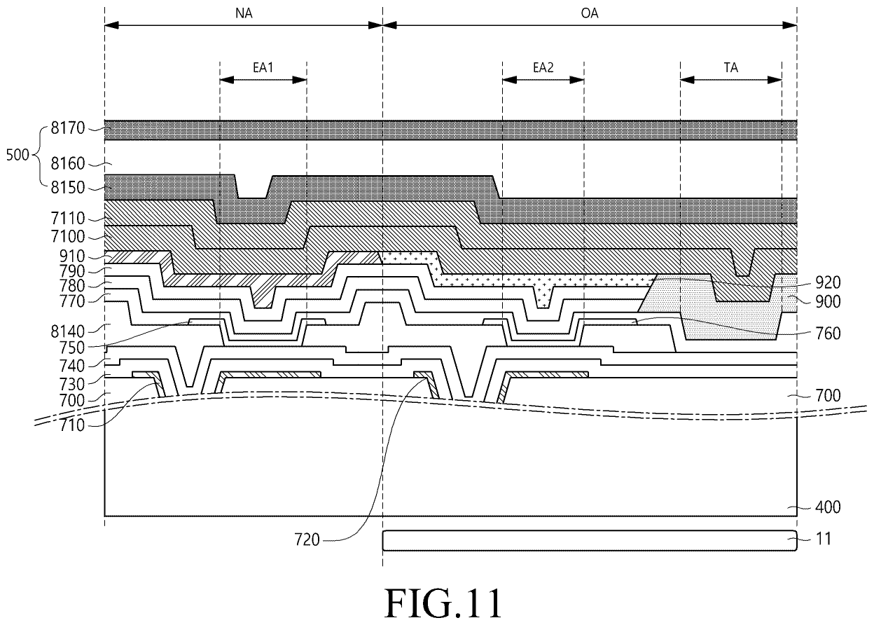

FIG. 11 is a view illustrating a normal area NA and an optical area OA of a display panel 110 according to embodiments of the disclosure.

In the cross-sectional view illustrated in FIG. 11, the illustration from the substrate 400 to the planarization layer 700 is omitted, and the omitted configuration can be the same as the configuration from the substrate 400 to the planarization layer 700 illustrated in FIG. 8. Further, the arrangement of the components illustrated in the cross-sectional view illustrating FIG. 11 is the same as the arrangement of the components illustrated in FIG. 9.

The arrangement of the normal area NA of the display panel 110 is described with reference to FIG. 11.

Referring to FIG. 11, a planarization layer 700 can be disposed on the substrate 400 of the normal area NA. A first anode electrode 710 can be disposed on the planarization layer 700. The first anode electrode 710 can be disposed to overlap the first emission area EA1.

A hole injection layer 730 can be disposed on the first anode electrode 710. A hole transport layer 740 can be disposed on the hole injection layer 730. A bank 8140 can be disposed on the hole transport layer 740. The bank 8140 can be disposed to have an opening in an area corresponding to the first emission area EA1.

The first light emitting layer 750 can be disposed on the bank 8140 to correspond to the first emission area EA1. The first light emitting layer 750 can contact the hole transport layer 740 at the opening formed in the first emission area EA1 of the bank 8140. An electron transport layer 770 can be disposed on the first light emitting layer 750. An electron injection layer 780 can be disposed on the electron transport layer 770. A first cathode electrode 790 can be disposed on the electron injection layer 780.

The light emitting element ED can be formed by the first anode electrode 710, the hole injection layer 730, the hole transport layer 740, the first light emitting layer 750, the electron transport layer 770, the electron injection layer 780, and the first cathode electrode 790 of the first emission area EA1.

A second patterning layer 910 can be disposed on the first cathode electrode 790. Therefore, the probability of desorption of metal on the surface of the second patterning layer 910 during metal deposition on the second patterning layer 910 increases significantly, and metal nucleation does not occur.

A first capping layer 7100 can be disposed on the second patterning layer 910. A second capping layer 7110 can be disposed on the first capping layer 7100. The first capping layer 7100 and the second capping layer 7110 can be formed together during an organic material deposition process, and the material thereof can be an organic material or an inorganic material.

An encapsulation layer 500 can be disposed on the second capping layer 7110. The encapsulation layer 500 can have a single layer structure or a multilayer structure. For example, the encapsulation layer 500 illustrated in FIG. 11 includes the first encapsulation layer 8150, the second encapsulation layer 8160, and the third encapsulation layer 8170 illustrated in FIG. 8.

Next, a cross-sectional view of the second emission area EA2 of the optical area OA is described with reference to FIG. 11.

Referring to FIG. 11, a planarization layer 700 can be disposed on the substrate 400 of the second emission area EA2 in the optical area OA. A second anode electrode 720 can be disposed on the planarization layer 700. The second anode electrode 720 can be disposed to overlap the second emission area EA2.

A hole injection layer 730 can be disposed on the second anode electrode 720. A hole transport layer 740 can be disposed on the hole injection layer 730. A bank 8140 can be disposed on the hole transport layer 740. The bank 8140 can be disposed to have an opening in an area corresponding to the second emission area EA2.

The second light emitting layer 760 can be disposed on the bank 8140 to correspond to the second emission area EA2. The second light emitting layer 760 can contact the hole transport layer 740 at the opening formed in the second emission area EA2 of the bank 8140. An electron transport layer 770 can be disposed on the second light emitting layer 760. An electron injection layer 780 can be disposed on the electron transport layer 770. A first cathode electrode 790 can be disposed on the electron injection layer 780.

The second cathode electrode 920 can be disposed on the first cathode electrode 790. A first capping layer 7100 can be disposed on the second cathode electrode 920. A second capping layer 7110 can be disposed on the first capping layer 7100. An encapsulation layer 500 can be disposed on the second capping layer 7110, and the configuration of the encapsulation layer 500 can be the same as the configuration of the encapsulation layer 500 of the normal area NA.

Next, a cross-sectional view of the transmissive area TA of the optical area OA is described with reference to FIG. 11.

Referring to FIG. 11, a planarization layer 700 can be disposed on the substrate 400 of the transmissive area TA of the optical area OA. A hole injection layer 730 can be disposed on the planarization layer 700. A hole transport layer 740 can be disposed on the hole injection layer 730. An electron transport layer 770 can be disposed on the hole transport layer 740.

The first patterning layer 900 can be disposed on the electron transport layer 770. A first capping layer 7100 can be disposed on the first patterning layer 900. A second capping layer 7110 can be disposed on the first capping layer 7100. An encapsulation layer 500 can be disposed on the second capping layer 7110, and the configuration of the encapsulation layer 500 can be the same as the configuration of the encapsulation layer 500 of the normal area NA.

Although FIG. 11 illustrates that the first patterning layer 900 is disposed on the electron transport layer 770, the electron injection layer 780 can be disposed on the electron transport layer 770 in the transmissive area TA, and the first patterning layer 900 can be disposed on the electron injection layer 780.

When the first patterning layer 900 is disposed on the electron transport layer 770, the first patterning layer 900 can be disposed adjacent to side surfaces of the electron injection layer 780, the first cathode electrode 790, and the second cathode electrode 920. In this case, the thickness of the first patterning layer 900 can be the same as the sum of the thickness of the electron injection layer 780, the thickness of the first cathode electrode 790, and the thickness of the second cathode electrode 920.

The second patterning layer 910 disposed in the normal area NA can be disposed adjacent to a side surface of the second cathode electrode 920 disposed in the optical area OA. The second patterning layer 910 can have the same thickness as the second cathode electrode 920.

Meanwhile, the second cathode electrode 920 can be disposed in the second emission area EA2 of the optical area OA by the first patterning layer 900 disposed in the transmissive area TA of the optical area OA and the second patterning layer 910 disposed in the normal area NA. In other words, the second cathode electrode 920 may not be disposed in the normal area NA and the transmissive area TA of the optical area OA.

As the second cathode electrode 920 is disposed in the second emission area EA2 of the optical area OA, the luminous efficiency of light output from the second light emitting layer 760 of the second emission area EA2 can be enhanced. Specifically, a micro cavity effect can be induced due to the difference in refractive index between the layer as the light emitted from the second light emitting layer 760 passes through the second cathode electrode 920, the first capping layer 7100, and the second capping layer 7110.

Therefore, it is possible to reduce the luminance deviation between the optical area OA and the normal area NA, which occurs because the density of subpixels SP in the optical area OA is smaller than the density of subpixels SP in the normal area NA.

Meanwhile, the first patterning layer 900 and the second patterning layer 910 can be disposed to have various thicknesses. For example, the thickness of the first patterning layer 900 can be larger than the thickness of the second patterning layer 910. Alternatively, the thickness of the first patterning layer 900 can be smaller than that of the second patterning layer 910.

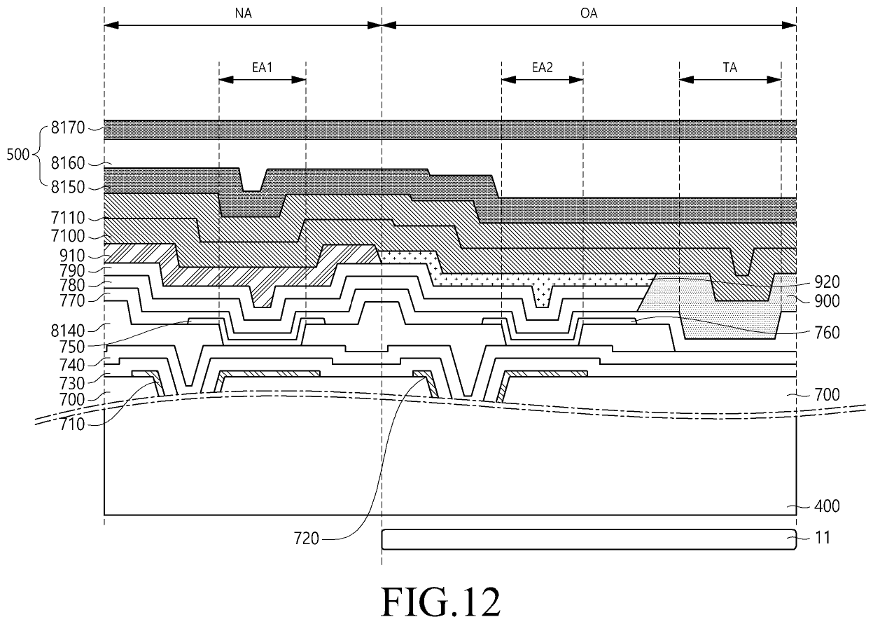

FIG. 12 is a view illustrating a normal area NA and an optical area OA of a display panel 110 according to embodiments of the disclosure.

The structure illustrated in the cross-sectional view of the display panel 110 according to FIG. 12 can have the same configuration and arrangement as the cross-sectional view of the display panel 110 illustrated in FIG. 11 except for the thickness of the second patterning layer 910. Accordingly, the description of the other components except for the second patterning layer 910 is omitted.

Referring to FIG. 12, the thickness of the second patterning layer 910 disposed in the normal area NA can be larger than the thickness of the second cathode electrode 920 disposed in the optical area OA. Therefore, the side surface of the second patterning layer 910 can be disposed adjacent to the side surface of the second cathode electrode 920 and the first capping layer 7100.

Meanwhile, the first patterning layer 900 can also have various thicknesses.

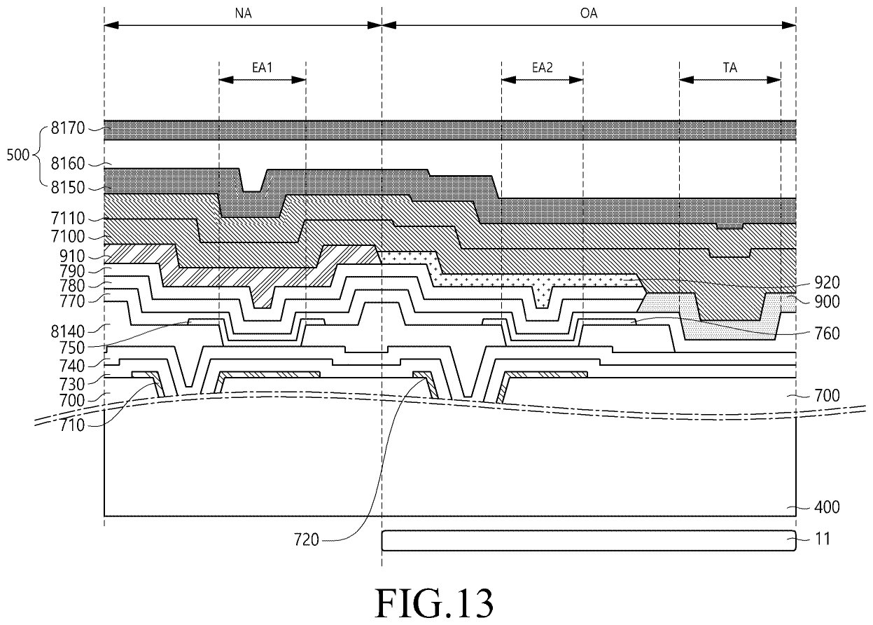

FIG. 13 is a view illustrating a normal area NA and an optical area OA of a display panel 110 according to embodiments of the disclosure.

The structure illustrated in the cross-sectional view of the display panel 110 according to FIG. 13 can have the same configuration and arrangement as the cross-sectional view of the display panel 110 illustrated in FIG. 12 except for the thickness of the first patterning layer 900. Accordingly, the description of the remaining components except for the first patterning layer 900 is omitted.

Referring to FIG. 13, the thickness of the first patterning layer 900 disposed in the transmissive area TA of the optical area OA can be smaller than the sum of the thicknesses of the electron injection layer 780 and the first cathode electrode 790 disposed in the second emission area EA2.

Further, the thickness of the first patterning layer 900 can be smaller than that of the second patterning layer 910.

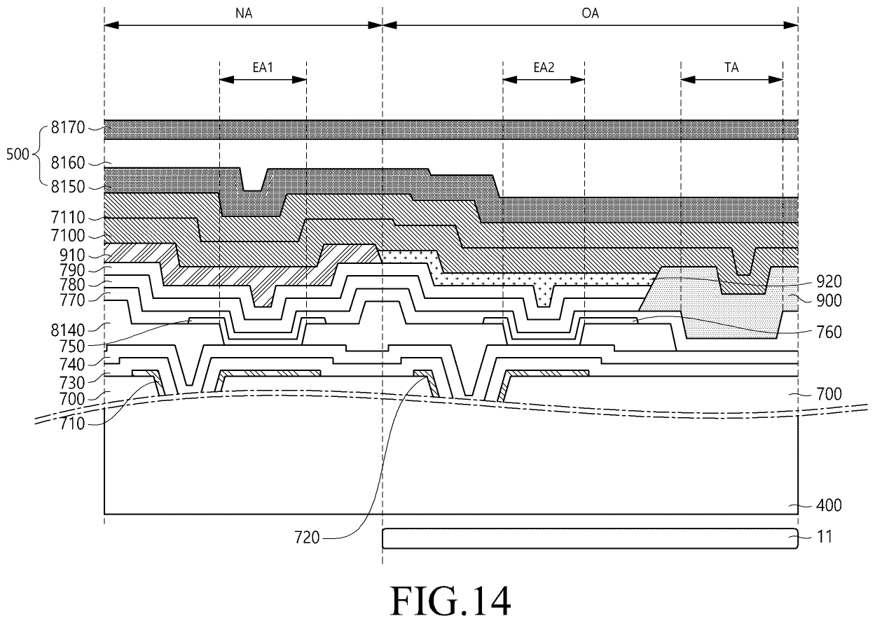

FIG. 14 is a view illustrating a normal area NA and an optical area OA of a display panel 110 according to embodiments of the disclosure.

The structure illustrated in the cross-sectional view of the display panel 110 according to FIG. 14 can have the same configuration and arrangement as the cross-sectional view of the display panel 110 illustrated in FIG. 12 except for the thickness of the first patterning layer 900. Accordingly, the description of the remaining components except for the first patterning layer 900 is omitted.

Referring to FIG. 14, the thickness of the first patterning layer 900 disposed in the transmissive area TA of the optical area OA can be larger than the sum of the thicknesses of the electron injection layer 780, the first cathode electrode 790, and the second cathode electrode 920 disposed in the second emission area EA2.

Therefore, the side surface of the first patterning layer 900 can be adjacent to the electron injection layer 780, the first cathode electrode 790, the second cathode electrode 920, and the first capping layer 7100 disposed in the optical area OA.

The thickness of the first patterning layer 900 and the thickness of the second patterning layer 910 can be varied according to the material forming the first patterning layer 900 and the second patterning layer 910 in addition to those described in FIGS. 11, 12, 13, and 14.

Meanwhile, the second cathode electrode 920 disposed in the second emission area EA2 of the optical area OA can be disposed to have various thicknesses.

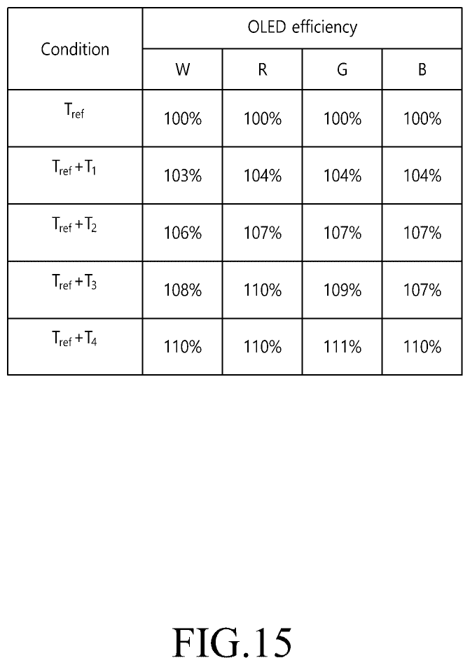

FIG. 15 is a subpixel SP-specific luminance efficiency table for each thickness of a second cathode electrode 920 according to embodiments of the disclosure.

Referring to FIG. 15, Tref can be the thickness of the first cathode electrode 790. T1, T2, T3, and T4 can be the thicknesses of the second cathode electrode 920. Specifically, T1 can be a thickness of the second cathode electrode 920 which is 1 nm. T2 can be a thickness of the second cathode electrode 920 of 2 nm. T3 can be a thickness of the second cathode electrode 920 of 3 nm. T4 can be a thickness of the second cathode electrode 920 of 4 nm.

As illustrated in FIG. 7, when the second cathode electrode 920 is not disposed in the second emission area EA2 but only the first cathode electrode 790 is disposed, it corresponds to Tref, and in this case, it can be assumed that the light output from the second emission area EA2 has a luminous efficiency of 100% for each of white (W), red (R), green (G), and blue (B) subpixels SP.

As illustrated in FIG. 9, when the second cathode electrode 920 is disposed on the first cathode electrode 790 of the second emission area EA2, a case in which the second cathode electrode is 1 nm can correspond to Tref+T1. In this case, the luminous efficiency of the W subpixel SP can be 103%. The luminous efficiency of the R subpixel SP can be 104%. The luminous efficiency of the G subpixel SP can be 104%. The luminous efficiency of the B subpixel SP can be 104%.

When the second cathode electrode 920 disposed on the first cathode electrode 790 of the second emission area EA2 is 2 nm, it can correspond to Tref+T2. In this case, the luminous efficiency of the W subpixel SP can be 106%. The luminous efficiency of the R subpixel SP can be 107%. The luminous efficiency of the G subpixel SP can be 107%. The luminous efficiency of the B subpixel SP can be 107%.

When the second cathode electrode 920 disposed on the first cathode electrode 790 of the second emission area EA2 is 3 nm, it can correspond to Tref+T3. In this case, the luminous efficiency of the W subpixel SP can be 108%. The luminous efficiency of the R subpixel SP can be 110%. The luminous efficiency of the G subpixel SP can be 109%. The luminous efficiency of the B subpixel SP can be 107%.

When the second cathode electrode 920 disposed on the first cathode electrode 790 of the second emission area EA2 is 4 nm, it can correspond to Tref+T4. In this case, the luminous efficiency of the W subpixel SP can be 110%. The luminous efficiency of the R subpixel SP can be 110%. The luminous efficiency of the G subpixel SP can be 111%. The luminous efficiency of the B subpixel SP can be 110%.

As described above, when the second cathode electrode 920 is disposed on the first cathode electrode 790 of the second emission area EA2, it is possible to enhancing luminous efficiency although the extent of the enhancement depends on the thickness. The thickness of the second cathode electrode 920 described in FIG. 15 is merely an example for description, and the thickness of the second cathode electrode 920 is not limited to such examples.

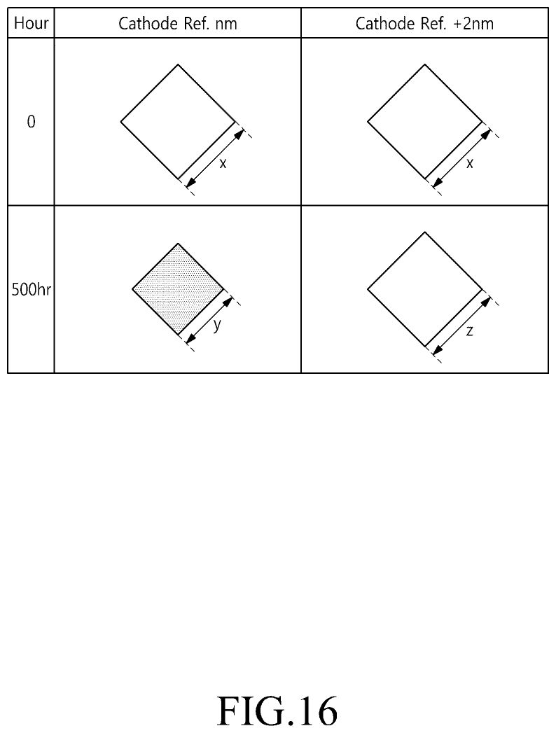

FIG. 16 is a table showing the degree of shrinkage and luminance degradation over time when a light emitting element ED is irradiated with an electromagnetic wave in a UV band according to embodiments of the disclosure.

Referring to FIG. 16, Cathode Ref. nm indicates the degree of shrinkage and luminance deterioration of the light emitting element ED due to exposure to electromagnetic waves in the UV band when the second cathode electrode 920 is not disposed in the second emission area EA2 of the optical area OA. As illustrated in the table of FIG. 16, when exposed to electromagnetic waves in the UV band for 500 hours, the size of the light emitting element ED can shrink and the luminance can deteriorate. Specifically, luminance can be decreased by more than 5%. When the length of the light emitting element ED before exposure to electromagnetic waves in the UV band is x, and the length of the light emitting element ED after exposure is y, y can be smaller. A defect rate of about 40% can occur due to shrinkage of the light emitting element ED.

The luminance deterioration and size shrinkage of the light emitting element ED can be caused by electromagnetic waves in the UV band transmitted through the optical area OA.

Further, Cathode Ref. +2 nm indicates the degree of shrinkage and luminance deterioration of the light emitting element ED due to exposure to electromagnetic waves in the UV band when a 2 nm-thick second cathode electrode 920 is disposed on the first cathode electrode 790 of the second emission area EA2. As illustrated in the table of FIG. 16, when exposed to electromagnetic waves in the UV band for 500 hours, the degree of size shrinkage and luminance deterioration of the light emitting element ED can be negligible compared to when the second cathode electrode 920 is not disposed. As the second cathode electrode 920 is disposed, luminance degradation and size shrinkage of the light emitting element ED in the optical area OA can scarcely occur.

As described above, it is possible to shield electromagnetic waves in the UV band radiated from the outside of the display panel 110 by disposing the second cathode electrode 920 in the optical area OA. Accordingly, it is possible to prevent the luminance deterioration and size shrinkage of the light emitting element ED compared to when the second cathode electrode 920 is not disposed in the optical area OA.

Embodiments of the disclosure described above are briefly described below.

A display device can comprise a substrate including a first area including a plurality of first emission areas and a second area including a plurality of second emission areas and a plurality of transmissive areas, a plurality of first anode electrodes respectively disposed in the plurality of first emission areas and positioned on the substrate, a plurality of second anode electrodes respectively disposed in the plurality of second emission areas and positioned on the substrate, a plurality of first light emitting layers disposed on the plurality of first anode electrodes, a plurality of second light emitting layers disposed on the plurality of second anode electrodes, a first cathode electrode disposed on the plurality of first light emitting layers and the plurality of second light emitting layers, a second cathode electrode disposed in the plurality of second emission areas and positioned on the first cathode electrode, a first patterning layer disposed in the plurality of transmissive areas and positioned on a side surface of the first cathode electrode, and a second patterning layer disposed in the plurality of first emission areas, positioned on the first cathode electrode, and positioned on a side surface of the second cathode electrode.

In the display device, at least a portion of the second cathode electrode may not overlap the first patterning layer of the plurality of transmissive areas.

The display device can further comprise an electron transport layer disposed in the first area and the second area and positioned on the plurality of first light emitting layers and the plurality of second light emitting layers, and an electron injection layer disposed in the plurality of first emission areas and the plurality of second emission areas and positioned between the electron transport layer and the first cathode electrode.

In the display device, the first patterning layer can be disposed on the electron transport layer in the plurality of transmissive areas.

In the display device, the electron injection layer can be positioned on a side surface of the first patterning layer.

In the display device, the electron injection layer can be also disposed in the plurality of transmissive areas on the electron transport layer. The first patterning layer can be disposed on the electron injection layer in the plurality of transmissive areas.

In the display device, a thickness of the first patterning layer can be equal to or larger than a thickness of the second patterning layer.

In the display device, a thickness of the first patterning layer can be smaller than a thickness of the second patterning layer.

In the display device, the electron injection layer can include an alkali metal.

In the display device, a thickness of the first patterning layer can be smaller than a sum of a thickness of the electron injection layer, a thickness of the first cathode electrode, and a thickness of the second cathode electrode.

In the display device, a thickness of the first patterning layer can be equal to or larger than a sum of a thickness of the electron injection layer, a thickness of the first cathode electrode, and a thickness of the second cathode electrode.

In the display device, a thickness of the first patterning layer can be larger than a thickness of the electron injection layer.

In the display device, a thickness of the second patterning layer can be equal to or larger than a thickness of the second cathode electrode.

The display device can further comprise a first capping layer disposed in the first area and the second area and positioned on the second cathode electrode and the second patterning layer, a second capping layer disposed on the first capping layer, and an encapsulation layer disposed on the second capping layer.

In the display device, a refractive index of the first capping layer can be higher than a refractive index of the second capping layer and a refractive index of the second patterning layer.

In the display device, the second cathode electrode can shield an electromagnetic wave in an ultraviolet wavelength band.

In the display device, an optical electronic device can be disposed on a rear surface of the second area. The optical electronic device can perform a predefined operation using light transmitted through the second area.

A display device can comprise a substrate including a display area in which a plurality of first emission areas are disposed, a plurality of first anode electrodes respectively disposed in the plurality of first emission areas and positioned on the substrate, a plurality of first light emitting layers disposed on the plurality of first anode electrodes, a first cathode electrode disposed on the plurality of first light emitting layers, a patterning layer positioned on the first cathode electrode, and a second cathode electrode disposed on a side surface of the patterning layer.

The above description has been presented to enable any person skilled in the art to make and use the technical idea of the disclosure, and has been provided in the context of a particular application and its requirements. Various modifications, additions and substitutions to the described embodiments will be readily apparent to those skilled in the art, and the general principles defined herein can be applied to other embodiments and applications without departing from the spirit and scope of the disclosure. The above description and the accompanying drawings provide an example of the technical idea of the disclosure for illustrative purposes only. That is, the disclosed embodiments are intended to illustrate the scope of the technical idea of the disclosure.

What is claimed:

1. A display device, comprising:
a substrate including a first area and a second area, the first area including a plurality of first emission areas and the second area including a plurality of second emission areas and a plurality of transmissive areas;
a plurality of first anode electrodes respectively disposed in the plurality of first emission areas and positioned on the substrate;
a plurality of second anode electrodes respectively disposed in the plurality of second emission areas and positioned on the substrate;
a plurality of first light emitting layers disposed on the plurality of first anode electrodes;
a plurality of second light emitting layers disposed on the plurality of second anode electrodes;
a first cathode electrode disposed on the plurality of first light emitting layers and the plurality of second light emitting layers;
a second cathode electrode disposed in the plurality of second emission areas and positioned on the first cathode electrode;
a first patterning layer disposed in the plurality of transmissive areas and adjacent to a side surface of the first cathode electrode in a first direction; and
a second patterning layer disposed in the plurality of first emission areas, positioned on the first cathode electrode, and adjacent to a side surface of the second cathode electrode in the first direction.

2. The display device of claim 1, wherein the first cathode electrode and the second cathode electrode have different refractive indexes.

3. The display device of claim 1, wherein each of the first patterning layer and the second patterning layer comprises a material that inhibits metal nucleation.

4. The display device of claim 1, wherein at least a portion of the second cathode electrode does not overlap the first patterning layer in a second direction being perpendicular to the first direction.

5. The display device of claim 1, further comprising:
an electron transport layer positioned on the plurality of first light emitting layers and the plurality of second light emitting layers; and
an electron injection layer positioned between the electron transport layer and the first cathode electrode.

6. The display device of claim 5, wherein the electron transport layer is disposed in the plurality of transmissive areas, and
wherein the first patterning layer is disposed on the electron transport layer.

7. The display device of claim 5, wherein the electron injection layer is adjacent to a side surface of the first patterning layer in the first direction.

8. The display device of claim 5, wherein the electron transport layer and the electron injection layer are disposed in the plurality of transmissive areas, and
wherein the electron injection layer in the plurality of transmissive areas is disposed between the electron transport layer and the first patterning layer.

9. The display device of claim 1, wherein a thickness of the first patterning layer is equal to or larger than a thickness of the second patterning layer.

10. The display device of claim 1, wherein a thickness of the first patterning layer is smaller than a thickness of the second patterning layer.

11. The display device of claim 5, wherein the electron injection layer includes an alkali metal.

12. The display device of claim 5, wherein a thickness of the first patterning layer is smaller than a sum of a thickness of the electron injection layer, a thickness of the first cathode electrode, and a thickness of the second cathode electrode.

13. The display device of claim 5, wherein a thickness of the first patterning layer is equal to or larger than a sum of a thickness of the electron injection layer, a thickness of the first cathode electrode, and a thickness of the second cathode electrode.

14. The display device of claim 5, wherein a thickness of the first patterning layer is larger than a thickness of the electron injection layer.

15. The display device of claim 1, wherein a thickness of the second patterning layer is equal to or larger than a thickness of the second cathode electrode.

16. The display device of claim 1, further comprising:
a first capping layer disposed on the first patterning layer, the second cathode electrode and the second patterning layer;
a second capping layer disposed on the first capping layer; and
an encapsulation layer disposed on the second capping layer.

17. The display device of claim 16, wherein a refractive index of the first capping layer is higher than a refractive index of the second capping layer and a refractive index of the second cathode electrode.

18. The display device of claim 1, wherein the second cathode electrode shields an electromagnetic wave in an ultraviolet wavelength band.

19. The display device of claim 1, further comprising:
an optical electronic device disposed on a rear surface of the second area,
wherein the optical electronic device performs a predefined operation using light transmitted through the plurality of transmissive areas.

20. A display device, comprising:
a substrate;
a plurality of anode electrodes positioned on the substrate;
a plurality of first light emitting layers and a plurality of second light emitting layers respectively disposed on the plurality of anode electrodes;
a first cathode electrode disposed on the plurality of first light emitting layers and the plurality of second light emitting layers;
a patterning layer disposed on the first cathode electrode and overlapping the plurality of first light emitting layers in a second direction; and
a second cathode electrode disposed on the first cathode electrode and overlapping the plurality of second light emitting layers in the second direction,
wherein the second cathode electrode is adjacent to a side surface of the patterning layer in a first direction perpendicular to the second direction.
